(19) United States
(12) Patent Application Publication
(10) Pub. No.: US 2026/0332908 A1
(43) Pub. Date: Oct. 22, 2026

(54) IMAGE SENSING DEVICE

(71) Applicant: SK hynix Inc., Icheon-si (KR)

(72) Inventor: Jae Hyung JANG, Icheon-si (KR)

(21) Appl. No.: 19/383,385

(22) Filed: Nov. 7, 2025

(30) Foreign Application Priority Data
Apr. 18, 2025 (KR) 10-2025-0050668

(51) Int. Cl. H04N 25/771; H04N 25/42; H04N 25/532

(52) U.S. Cl. CPC H04N 25/771; H04N 25/42; H04N 25/532

(57) ABSTRACT

Image sensing devices are disclosed. In an embodiment, an image sensing device includes a semiconductor substrate and a pixel array including a plurality of pixels, each including a photoelectric conversion region. Each of the plurality of pixels further includes first and second tap regions disposed in a semiconductor substrate, each of the first and second tap regions configured to capture photocharges generated by the photoelectric conversion region, a first floating diffusion region disposed in the semiconductor substrate and having a first capacitance to accumulate the photocharges captured by the first tap region, a second floating diffusion region disposed in the semiconductor substrate and having a second capacitance to accumulate the photocharges captured by the second tap region, and a capacitor electrically connected in parallel to the second floating diffusion region and configured to modify an effective capacitance of the second floating diffusion region having the second capacitance.

### CROSS-REFERENCE TO RELATED APPLICATION

This application claims the priority and benefits of Korean Patent Application No. 10-2025-0050668 filed on Apr. 18, 2025, the entire contents of which are incorporated herein by reference.

### TECHNICAL FIELD

The technology and implementations disclosed in this patent document generally relate to an image sensing device, and more particularly to an image sensing device including a capacitor connected to a floating diffusion region.

### BACKGROUND

An image sensing device captures an optical image by using the properties of photosensitive semiconductor materials, which react to a light. With advancements in the automotive, medical, computer and communication industries, the demand for high-performance image sensing devices is growing across various fields such as smartphones, digital cameras, game machines, IoT (Internet of Things), robots, security cameras, and medical micro cameras.

Image sensing devices are generally classified as charge coupled device (CCD) image sensing devices or complementary metal oxide semiconductor devices (CMOS) image sensing devices. CCD image sensing devices provide better image quality than CMOS image sensing devices. However, CCD image sensing devices are larger in size and consume more power than CMOS image sensing devices. In addition, because CMOS image sensing devices are manufactured by using CMOS technology, both the light-sensing element and the signal-processing circuit can be integrated into a single chip. This integration allows for the production of compact, low-cost image sensing devices. For these reasons, CMOS image sensing devices are being used for a wide range of applications, including mobile devices.

### SUMMARY

The disclosed technology can be implemented in some embodiments to address the above-mentioned issues of the existing technology, while preserving its advantages.

An aspect of the disclosed technology provides an image sensing device designed to set a wider dynamic range of an electrical signal generated by a unit pixel.

An aspect of the disclosed technology provides an image sensing device designed to capture fast-moving subjects or producing high-quality video while maintaining a wide dynamic range.

In an aspect of the disclosed technology, an image sensing device may include a semiconductor substrate, and a pixel array disposed at least partially in the semiconductor substrate and including a plurality of pixels, each of the plurality of pixels including a photoelectric conversion region configured to generate electrical signals in response to incident light. Each of the plurality of pixels may further include a first tap region and a second tap region that are disposed in the semiconductor substrate, each of the first and second tap regions configured to capture photocharges generated in response to the incident light, a first floating diffusion region disposed in the semiconductor substrate and coupled to the first tap region, the first floating diffusion region having a first capacitance and configured to accumulate the photocharges captured by the first tap region, a second floating diffusion region disposed in the semiconductor substrate and coupled to the second tap region, the second floating diffusion region having a second capacitance and configured to accumulate the photocharges captured by the second tap region, and a capacitor electrically connected in parallel to the second floating diffusion region and configured to modify an effective capacitance of the second floating diffusion region having the second capacitance. In an embodiment, the capacitor is spaced apart from a first surface of the semiconductor substrate, is connected to the second floating diffusion region, and at least partially overlaps the first tap region, or the second tap region, or both the first and second tap regions.

In an embodiment of the disclosed technology, the image sensing device may further include a first well region surrounding the first floating diffusion region and having a first depth from the first surface of the semiconductor substrate, and a second well region surrounding the second floating diffusion region and having a second depth from the first surface of the semiconductor substrate.

In an embodiment of the disclosed technology, the first depth may be larger than the second depth.

In an embodiment of the disclosed technology, the first tap region may include a first control node having a third depth from the first surface of the semiconductor substrate, and the second tap region may include a second control node having a fourth depth from the first surface of the semiconductor substrate.

In an embodiment of the disclosed technology, the third depth may be larger than the fourth depth.

In an embodiment of the disclosed technology, the first tap region may further include a first detection node having a fifth depth from the first surface of the semiconductor substrate and configured to capture the photocharges, and the second tap region may further include a second detection node having a sixth depth from the first surface of the semiconductor substrate and configured to capture the photocharges.

In an embodiment of the disclosed technology, the fifth depth may be smaller than the sixth depth.

In an embodiment of the disclosed technology, each of the first floating diffusion region, the second floating diffusion region, the first detection node, and the second detection node may include impurities of a first conductivity type, and each of the first well region, the second well region, the first control node, and the second control node may include impurities of a second conductivity type.

In an embodiment of the disclosed technology, the first tap region may operate in a first mode in which illuminance according to the incident light is less than a first threshold, and the second tap region may operate in a second mode in which the illuminance according to the incident light is greater than a second threshold that is greater than or equal to the first threshold.

In an embodiment of the disclosed technology, an electrical signal corresponding to photocharges accumulated in the first floating diffusion region may be generated in response to operation of the first tap region, and an electrical signal corresponding to photocharges accumulated in the second floating diffusion region may be generated in response to operation of the second tap region.

In an embodiment of the disclosed technology, both the first tap region and the second tap region may operate in a third mode in which the illuminance according to the incident light is between the first threshold and the second threshold.

In an embodiment of the disclosed technology, the first tap region and the second tap region may operate alternately in the third mode.

In an embodiment of the disclosed technology, the pixel array may operate in a global shutter mode.

In an embodiment of the disclosed technology, an image sensing device may include a substrate that includes a photoelectric conversion region generating photocharges in response to incident light, and first and second tap regions configured to capture the photocharges, and a capacitor that is spaced apart from a first surface of the substrate and vertically overlaps each of the first tap region and the second tap region.

In an embodiment of the disclosed technology, the substrate may further include a first floating diffusion region electrically connected to the first tap region by a first transfer transistor, a first well region surrounding the first floating diffusion region and having a first depth from the first surface of the substrate, a second floating diffusion region electrically connected to the second tap region by a second transfer transistor, and a second well region surrounding the second floating diffusion region and having a second depth from the first surface of the substrate, and the capacitor and the second floating diffusion region may be electrically connected in parallel.

In an embodiment of the disclosed technology, the first depth may be larger than the second depth.

In an embodiment of the disclosed technology, the first tap region may include a first control node having a third depth from the first surface of the substrate, and the second tap region may include a second control node having a fourth depth from the first surface of the substrate.

In an embodiment of the disclosed technology, the third depth may be larger than the fourth depth.

In an embodiment of the disclosed technology, the first tap region may further include a first detection node having a fifth depth from the first surface of the substrate, and the second tap region may further include a second detection node having a sixth depth from the first surface of the substrate.

In an embodiment of the disclosed technology, the fifth depth may be smaller than the sixth depth.

### BRIEF DESCRIPTION OF THE DRAWINGS

FIG. 1 is a block diagram illustrating an example of an image sensing device based on an embodiment of the disclosed technology.

FIG. 2 is a circuit diagram illustrating an example of a circuit model of a unit pixel included in a pixel array of FIG. 1.

FIG. 3 is a cross-sectional view illustrating an example of a unit pixel included in a pixel array of FIG. 1.

FIG. 4 is a graph illustrating an example of an electric potential distribution of first and second floating diffusion regions in the circuit diagram of FIG. 2.

FIG. 5A is a graph illustrating an example of signal levels of first and second control signals when the circuit diagram of FIG. 2 operates in a first mode.

FIG. 5B is a graph illustrating an example of an electric potential distribution of first and second floating diffusion regions in an operating interval of FIG. 5A.

FIG. 6A is a graph illustrating an example of signal levels of first and second control signals when the circuit diagram of FIG. 2 operates in a second mode.

FIG. 6B is a graph illustrating an example of an electric potential distribution of first and second floating diffusion regions in an operating interval of FIG. 6A.

FIG. 7A is a graph illustrating an example of signal levels of first and second control signals when the circuit diagram of FIG. 2 operates in a third mode.

FIG. 7B is a graph illustrating an example of an electric potential distribution of first and second floating diffusion regions in a first operating interval of FIG. 7A.

FIG. 7C is a graph illustrating an example of an electric potential distribution of first and second floating diffusion regions in a second operating interval of FIG. 7A.

FIG. 8 is a plan view illustrating an example of a pixel group included in a pixel array of FIG. 1.

FIG. 9 is a cross-sectional view illustrating a first example configuration of the cross section taken along line A-A’ of FIG. 8.

FIG. 10 is a cross-sectional view illustrating a second example configuration of the cross section taken along line A-A’ of FIG. 8.

FIG. 11 is a cross-sectional view illustrating a third example configuration of the cross section taken along line A-A’ of FIG. 8.

FIG. 12 is a cross-sectional view illustrating a fourth example configuration of the cross section taken along line A-A’ of FIG. 8.

### DETAILED DESCRIPTION

Below, some embodiments of the disclosed technology will be described in detail with reference to the accompanying drawings. When assigning reference numerals/signs to components in each drawing, the same components are designated by the same numerals/signs, even when they are illustrated in different drawings. Also, in describing embodiments of the disclosed technology, when it is determined that a detailed description of known components or functions would hinder understanding of the embodiments of the disclosed technology, such detailed description will be omitted.

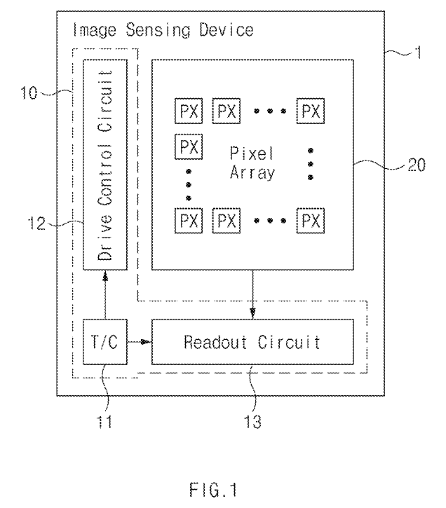

FIG. 1 is a block diagram illustrating an example of an image sensing device 1 based on an embodiment of the disclosed technology.

Referring to FIG. 1, the image sensing device 1 may include a control block 10 and a pixel array 20.

The control block 10 may be a block that controls all operations of the image sensing device 1, including an operation of controlling an operation of the pixel array 20. The control block 10 may include a timing control circuit (T/C) 11, a drive control circuit 12, and a readout circuit 13.

The timing control circuit 11 may provide a given timing signal and given control signals to at least one or more of the drive control circuit 12 and the readout circuit 13.

The drive control circuit 12 may activate the pixel array 20 based on the timing signal and control signals provided from the timing control circuit 11 such that there are performed specific operations on pixels PX included in the corresponding row.

In an embodiment, the drive control circuit 12 may select at least one pixel PX arranged on at least one row of the pixel array 20 and may supply a signal enabling the selected pixel PX to perform a specific operation, to the selected pixel PX. The drive control circuit 12 may generate a row selection signal to select at least one row among a plurality of rows. When a specific row is selected to perform a specific operation, the drive control circuit 12 may prevent a row adjacent to the selected specific row from performing the operation.

The pixels PX of the row selected by the drive control circuit 12 may sequentially transfer a reference signal and an image signal, both in an analog form, to the readout circuit 13. The reference signal may be an electrical signal that is provided to the readout circuit 13 when the floating diffusion region of the pixel PX is reset with a power supply voltage, and the image signal may be an electrical signal that is provided to the readout circuit 13 when photocharges generated by the pixel PX are accumulated in the floating diffusion region.

The reference signal may be a signal indicating a unique reset noise value of the pixel PX. In some embodiments, the reference signal and the image signal may be collectively referred to as a “pixel signal.”

The pixel array 20 may include a plurality of pixels PX arranged in a matrix including a plurality of rows and a plurality of columns. The plurality of pixels PX may be connected to the drive control circuit 12 through a plurality of row lines extending in the row direction. The plurality of pixels PX may be connected to the readout circuit 13 through a plurality of column lines extending in the column direction. The pixel array 20 may include a configuration in which at least one or more pixels PX are arranged in the row direction and the column direction. In the pixel array 20, for example, the plurality of pixels PX may be arranged in the shape of a two-dimensional pixel array (or in a matrix structure) including rows and columns. In some embodiments, the term “connected” can encompass both a physical connection and an electrical connection.

The plurality of pixels PX included in the pixel array 20 may convert a light signal into electrical signals (pixel signals) and may be connected to a given internal pixel circuit.

The pixel array 20 may be provided with the pixel control signal including a selection signal, a reset signal, a transfer signal, etc. from the drive control circuit 12, and at least one pixel PX included in the selected row may perform a specific operation in response to the pixel control signal from the drive control circuit 12, which includes the selection signal, the reset signal, and the transfer signal.

Each of the plurality of pixels PX included in the pixel array 20 may react to incident light incident from the outside and may output a pixel signal. The plurality of pixels PX may be arranged in a two-dimensional shape. For example, the plurality of pixels PX may be arranged in a matrix structure. The plurality of pixels PX may be disposed along the row direction and the column direction.

In the light incident onto the pixel PX, a light in a specific wavelength band (e.g., a red light, a green light, or a blue light) may pass through an optical filter disposed within the pixel PX, and the light passing through the optical filter may be integrated in a photoelectric conversion region. Photocharges corresponding to the incident light may be generated in the photoelectric conversion region. An electrical signal corresponding to the amount of photocharges thus generated may be generated by the pixel PX.

When the pixel PX operates under very low or no incident light, the pixel PX may generate a dark signal. The signal generated under the dark condition may be a signal corresponding to a noise component generated within the image sensing device 1.

The readout circuit 13 may sample electrical signals output from the pixel array 20 and may convert the sampled electrical signals into digital signals and output them to an image signal processor (not illustrated). The readout circuit 13 may include, for example, a correlated double sampler (not illustrated), an analog-to-digital (A/D) converter (not illustrated), an output buffer (not illustrated), a column driver (not illustrated), etc.

For example, the correlated double sampler may receive the reference signal and the image signal corresponding to each of the columns of the pixel array 20 and may sample levels of the reference signal and the image signal. In the case of a CMOS-based image sensing device, the correlated double sampler may sample the pixel signal two times to remove a difference between two samples and may perform correlated double sampling such that an unwanted value of the pixel PX, such as a fixed noise, is capable of being removed. The correlated double sampler may remove, for example, an unwanted value by comparing voltages output from the pixel PX before and after photocharges generated by the incident light are accumulated in the floating diffusion region and may measure a pixel output voltage based on the incident light.

The correlated double sampler may transfer, as correlated double sampling (CDS) signals, reference signals and image signals generated at the columns to the A/D converter based on the timing signal or the control signal of the timing control circuit 11.

For example, the A/D converter may convert and output the CDS signals output from the correlated double sampler and having an analog form into digital signals.

The output buffer may temporarily hold and output the digital signals provided from the A/D converter.

The column driver may select columns in the output buffer based on the timing signal and the control signal of the timing control circuit 11 such that the temporarily held digital signals are output in the order of selecting the columns.

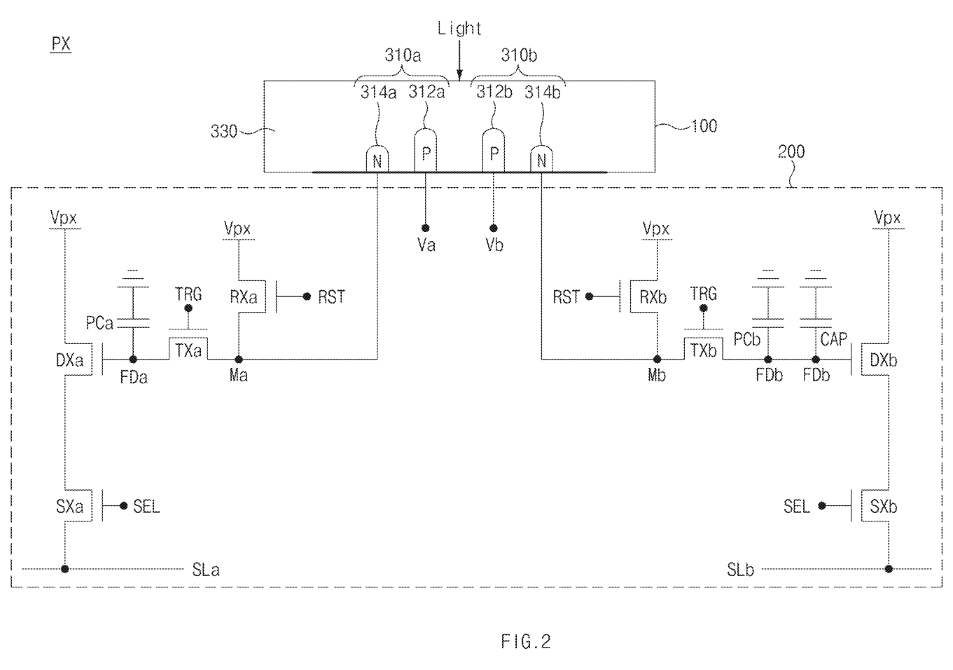

FIG. 2 is a circuit diagram illustrating a circuit model of the pixel PX included in the pixel array 20 of FIG. 1.

Referring to FIGS. 1 and 2, the pixel PX may include a substrate 100 and an internal circuit region 200.

The substrate 100 may include a photoelectric conversion region 330, which generates photocharges in response to light incident from the outside, and a plurality of tap regions 310a and 310b, which capture the photocharges.

The first tap region 310a may include a first detection node 314a and a first control node 312a. The first tap region 310a may be connected to a portion of the internal circuit region 200. The second tap region 310b may include a second detection node 314b and a second control node 312b. The second tap region 310b may be connected to another portion of the internal circuit region 200.

The first detection node 314a may be a region including impurities of a first conductivity type (e.g., n-type impurities). The first detection node 314a may be a region that is used to capture photocharges generated in the photoelectric conversion region 330. The first detection node 314a may be connected to a first terminal of a first transfer transistor TXa. The first detection node 314a may be connected to a first terminal of a first reset transistor RXa.

The second detection node 314b may be a region including the impurities of the first conductivity type. The second detection node 314b may be a region that is used to capture photocharges generated in the photoelectric conversion region 330. The second detection node 314b may be connected to a first terminal of a second transfer transistor TXb. The second detection node 314b may be connected to a first terminal of a second reset transistor RXb.

The first control node 312a may be a region including impurities of a second conductivity type (e.g., p-type impurities). The first control node 312a may receive a first control signal Va from the drive control circuit 12. The second control node 312b may be a region including the impurities of the second conductivity type. The second control node 312b may receive a second control signal Vb from the drive control circuit 12.

An electric potential difference of the first control signal Va and the second control signal Vb may cause the generation of a current in the photoelectric conversion region 330. The current may control the flow of the photocharges generated in the photoelectric conversion region 330.

For example, when the voltage of the first control signal Va is higher than the voltage of the second control signal Vb, the current may flow from the vicinity of the first control node 312a to the vicinity of the second control node 312b. In contrast, when the voltage of the first control signal Va is lower than the voltage of the second control signal Vb, the current may flow from the vicinity of the second control node 312b to the first control node 312a.

As the current flows, the first detection node 314a or the second detection node 314b may capture and accumulate the photocharges.

The photoelectric conversion region 330 may be a region in which the photoelectric effect is generated by the incident light incident onto the substrate 100, thereby generating photocharges corresponding to the incident light. The incident light may generate electron-hole pairs corresponding to the intensity of incident light depending on the photoelectric effect.

The internal circuit region 200 may include one or more circuits that generate an electrical signal corresponding to photocharges generated and captured in the substrate 100 and one or more circuits that output the electrical signal to the readout circuit 13. The internal circuit region 200 may include the first reset transistor RXa, the second reset transistor RXb, the first transfer transistor TXa, the second transfer transistor TXb, a first floating diffusion region FDa, a second floating diffusion region FDb, a first drive transistor DXa, a second drive transistor DXb, a first select transistor SXa, and a second select transistor SXb.

Control signals Va, Vb, RST, TRG, and SEL which are supplied to the internal circuit region 200 may be provided from the drive control circuit 12. A pixel voltage Vpx may be a power supply voltage.

The first reset transistor RXa may be set to an on-state or an off-state in response to a signal level of the reset signal RST applied to a gate electrode thereof. For example, when the reset signal RST has a high level, the first reset transistor RXa may be set to the on-state. When the first reset transistor RXa is in the on-state, a first medium node Ma may be reset. When the first transfer transistor TXa is in the on-state, the first reset transistor RXa may also be in the on-state; in this case, the first floating diffusion region FDa may also be reset together with the first medium node Ma. When the reset signal RST has a low level, the first reset transistor RXa may be set to the off-state, and thus, the reset of the first medium node Ma may be prevented. In some embodiments, the terms “high level” and “low level” can refer to logic high and low levels, respectively.

The second reset transistor RXb may be set to the on-state or the off-state in response to a signal level of the reset signal RST applied to a gate electrode thereof. When the reset signal RST has the high level, the second reset transistor RXb may be set to the on-state. When the second reset transistor RXb is in the on-state, a second medium node Mb may be reset. When the second reset transistor RXb is in the on-state, the second transfer transistor TXb may also be in the on-state; in this case, the second floating diffusion region FDb may also be reset together with the second medium node Mb. When the reset signal RST has the low level, the second reset transistor RXb may be set to the off-state, and thus, the reset of the second medium node Mb may be prevented.

The first transfer transistor TXa may be set to the on-state or the off-state in response to a signal level of the transfer signal TRG applied to a gate electrode thereof. When the transfer signal TRG has the high level, the first transfer transistor TXa may be set to the on-state. When the first transfer transistor TXa is in the on-state, the photocharges accumulated at the first detection node 314a may be transferred to the first floating diffusion region FDa through the first medium node Ma for accumulation. When the transfer signal TRG has the low level, the first transfer transistor TXa may be set to the off-state. When the first transfer transistor TXa is in the off-state, the first transfer transistor TXa may block the charge transfer between the first detection node 314a and the first floating diffusion region FDa.

The second transfer transistor TXb may be set to the on-state or the off-state in response to a signal level of the transfer signal TRG applied to a gate electrode thereof. When the transfer signal TRG has the high level, the second transfer transistor TXb may be set to the on-state. When the second transfer transistor TXb is in the on-state, the photocharges accumulated at the second detection node 314b may be transferred to the second floating diffusion region FDb through the second medium node Mb for accumulation. When the transfer signal TRG has the low level, the second transfer transistor TXb may be set to the off-state. When the second transfer transistor TXb is in the off-state, the second transfer transistor TXb may block the charge transfer between the second detection node 314b and the second floating diffusion region FDb.

The first floating diffusion region FDa may be connected to a gate electrode of the first drive transistor DXa. The first floating diffusion region FDa may be a node for accumulating the photocharges transferred from the first detection node 314a.

The second floating diffusion region FDb may be connected to a gate electrode of the second drive transistor DXb. The second floating diffusion region FDb may be a node for accumulating the photocharges transferred from the second detection node 314b.

A first parasitic capacitor PCa may be connected to the first floating diffusion region FDa. The first parasitic capacitor PCa may provide a given capacitance to the first floating diffusion region FDa.

A second parasitic capacitor PCb may be connected to the second floating diffusion region FDb. The second parasitic capacitor PCb may provide a given capacitance to the second floating diffusion region FDb.

A capacitor CAP may be connected to the second floating diffusion region FDb. The capacitor CAP may be connected in parallel with the second parasitic capacitor PCb. The capacitor CAP may be connected in parallel with the second floating diffusion region FDb. The capacitor CAP may provide a given capacitance to the second floating diffusion region FDb.

The second floating diffusion region FDb to which the capacitor CAP is connected may have a larger capacitance than the first floating diffusion region FDa not connected to the capacitor CAP; in this case, the second floating diffusion region FDb may accumulate more photocharges and may implement the high dynamic range (HDR). For example, in a high-illumination environment in which the amount of incident light is relatively large, a pixel signal may be output through the second floating diffusion region FDb. In contrast, in a low-illumination environment in which the amount of incident light is relatively small, a pixel signal may be output through the first floating diffusion region FDa. According to an embodiment, whether the pixel PX outputs a pixel signal through any floating diffusion region may be determined depending on an illuminance range.

The first drive transistor DXa may include a drain electrode connected to the pixel voltage Vpx and a source electrode connected to a first vertical signal line SLa through the first select transistor SXa. The gate electrode of the first drive transistor DXa may be connected to the first floating diffusion region FDa. The first drive transistor DXa may operate as a source follower transistor that outputs a current (pixel signal), the magnitude of which corresponds to an electric potential of the first floating diffusion region FDa.

The second drive transistor DXb may include a drain electrode connected to the pixel voltage Vpx and a source electrode connected to a second vertical signal line SLb through the second select transistor SXb. The gate electrode of the second drive transistor DXb may be connected to the second floating diffusion region FDb. The second drive transistor DXb may operate as a source follower transistor that outputs a current (pixel signal), the magnitude of which corresponds to an electric potential of the second floating diffusion region FDb.

The first select transistor SXa may be set to the on-state or the off-state depending on a signal level of the selection signal SEL applied to a gate electrode thereof. When the selection signal SEL has the high level, the first select transistor SXa may be set to the on-state. When the first select transistor SXa is in the on-state, the first select transistor SXa may output, to the first vertical signal line SLa, the pixel signal output from the first drive transistor DXa and has a magnitude corresponding to the potential of the first floating diffusion region FDa. The first vertical signal line SLa may be connected to the readout circuit 13. When the selection signal SEL has the low level, the first select transistor SXa may be set to the off-state. When the first select transistor SXa is in the off-state, the first select transistor SXa may prevent the pixel signal output from the first drive transistor DXa from being output to the first vertical signal line SLa.

The second select transistor SXb may be set to the on-state or the off-state depending on a signal level of the selection signal SEL applied to a gate electrode thereof. When the selection signal SEL has the high level, the second select transistor SXb may be set to the on-state. When the second select transistor SXb is in the on-state, the second select transistor SXb may output, to the second vertical signal line SLb, the pixel signal output from the second drive transistor DXb and has a magnitude corresponding to the electric potential of the second floating diffusion region FDb. The second vertical signal line SLb may be connected to the readout circuit 13. When the selection signal SEL has the low level, the second select transistor SXb may be set to the off-state. When the second select transistor SXb is in the off-state, the second select transistor SXb may prevent the pixel signal output from the second drive transistor DXb from being output to the second vertical signal line SLb.

A pixel signal output from any one of the first and second vertical signal lines SLa and SLb may be converted into image data through noise removal and analog-to-digital conversion in the readout circuit 13.

An example in which the same reset signal RST is applied to the first and second reset transistors RXa and RXb is illustrated in FIG. 2, but an embodiment of the disclosed technology may include an embodiment in which the reset signal RST applied to the first reset transistor RXa and the reset signal RST applied to the second reset transistor RXb are controlled independently of each other. Likewise, an example in which the same transfer signal TRG is applied to the first and second transfer transistors TXa and TXb is illustrated in FIG. 2, but an embodiment of the disclosed technology may include an embodiment in which the transfer signal TRG applied to the first transfer transistor TXa and the transfer signal TRG applied to the second transfer transistor TXb are controlled independently of each other. Also, an example in which the same selection signal SEL is applied to the first and second select transistors SXa and SXb is illustrated in FIG. 2, but an embodiment of the disclosed technology may include an embodiment in which the selection signal SEL applied to the first select transistor SXa and the selection signal SEL applied to the second select transistor SXb are controlled independently of each other.

An image signal processor (not illustrated) may generate an image by using the image data obtained from the photocharges captured at the first detection node 314a. The image signal processor may generate an image by using the image data obtained from the photocharges captured at the second detection node 314b.

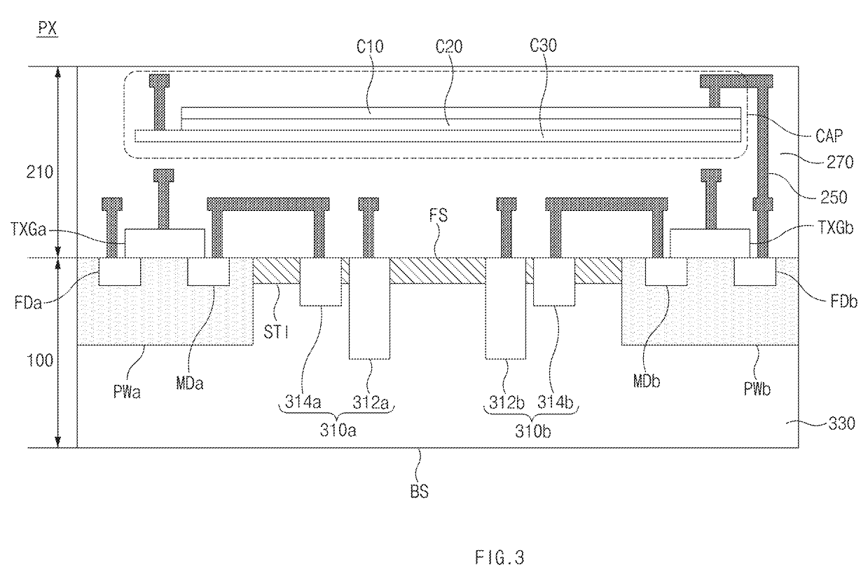

FIG. 3 is a cross-sectional view partially illustrating the pixel PX included in the pixel array 20 of FIG. 1.

Referring to FIGS. 2 and 3, the pixel PX may include the substrate 100 and a wiring (interconnect) region 210. The substrate 100 may include a back surface BS onto which the incident light is incident, and a front surface FS facing away from the back surface BS. The wiring region 210 may be disposed at a location adjacent to the front surface FS.

The substrate 100 may include a given doping structure formed by doping the inside of a semiconductor substrate with impurities and a given separation structure formed by forming a trench from one surface (e.g., the front surface FS) of the semiconductor substrate and filling the trench with an insulating material. For example, the substrate 100 may include given doping regions formed by injecting impurities of the first conductivity type (n-type) and impurities of the second conductivity type (p-type) into a semiconductor substrate including a silicon material (e.g., Si or SiGe). The substrate 100 may include a given separation structure for physically separating some of the doping regions.

The substrate 100 may include the first detection node 314a, the first control node 312a, a first medium node MDa, the first floating diffusion region FDa, a first well region PWa, the second detection node 314b, the second control node 312b, a second medium node MDb, the second floating diffusion region FDb, a second well region PWb, a first separation structure STI, and the photoelectric conversion region 330.

The first detection node 314a may be located on the front surface FS of the substrate 100. The first detection node 314a may be spaced apart from the back surface BS of the substrate 100. The first detection node 314a may be a region formed by injecting the impurities of the first conductivity type into the semiconductor substrate. The first detection node 314a may be disposed adjacent to one side of the first control node 312a. An embodiment in which the first detection node 314a is disposed on one side of the first control node 312a is illustrated in FIG. 3 by way of example, but an embodiment in which the first detection node 314a surrounds the first control node 312a is also possible. The first detection node 314a may be in contact with a wiring structure 250.

The first control node 312a may be located on the front surface FS of the substrate 100. The first control node 312a may be spaced apart from the back surface BS of the substrate 100. The first control node 312a may be a region formed by injecting the impurities of the second conductivity type into the semiconductor substrate. The first control node 312a may be in contact with the wiring structure 250.

The first medium node MDa may be located on the front surface FS of the substrate 100. The first medium node MDa may be spaced apart from the back surface BS of the substrate 100. The first medium node MDa may be a region formed by injecting the impurities of the first conductivity type into the semiconductor substrate. The first medium node MDa may be in contact with the wiring structure 250. The first medium node MDa may be disposed inside the first well region PWa.

The first floating diffusion region FDa may be located on the front surface FS of the substrate 100. The first floating diffusion region FDa may be spaced apart from the back surface BS of the substrate 100. The first floating diffusion region FDa may be a region formed by injecting the impurities of the first conductivity type into the semiconductor substrate. The first floating diffusion region FDa may be in contact with the wiring structure 250. The first floating diffusion region FDa may be disposed inside the first well region PWa.

The first well region PWa may be located on the front surface FS of the substrate 100. The first well region PWa may be spaced apart from the back surface BS of the substrate 100. The first well region PWa may be a region formed by injecting the impurities of the second conductivity type into the semiconductor substrate. The first well region PWa may surround the first medium node MDa and the first floating diffusion region FDa. For example, the first well region PWa may be in contact with side surfaces and a lower surface of each of the first medium node MDa and the first floating diffusion region FDa.

As a PN junction is formed between the first floating diffusion region FDa and the first well region PWa, a capacitance may be formed in the first floating diffusion region FDa. A circuit model obtained by modeling the capacitance formed by the PN junction in a circuit diagram may correspond to the first parasitic capacitor PCa of FIG. 2.

The second detection node 314b may be located on the front surface FS of the substrate 100. The second detection node 314b may be spaced apart from the back surface BS of the substrate 100. The second detection node 314b may be a region formed by injecting the impurities of the first conductivity type into the semiconductor substrate. The second detection node 314b may be disposed adjacent to one side of the second control node 312b. An embodiment in which the second detection node 314b is disposed on one side of the second control node 312b is illustrated in FIG. 3 by way of example, but an embodiment in which the second detection node 314b surrounds the second control node 312b is also possible. The second detection node 314b may be in contact with the wiring structure 250.

The second control node 312b may be located on the front surface FS of the substrate 100. The second control node 312b may be spaced apart from the back surface BS of the substrate 100. The second control node 312b may be a region formed by injecting impurities of the second conductivity type into the semiconductor substrate. The second control node 312b may be in contact with the wiring structure 250.

The second medium node MDb may be located on the front surface FS of the substrate 100. The second medium node MDb may be spaced apart from the back surface BS of the substrate 100. The second medium node MDb may be a region formed by injecting the impurities of the first conductivity type into the semiconductor substrate. The second medium node MDb may be in contact with the wiring structure 250. The second medium node MDb may be disposed inside the second well region PWb.

The second floating diffusion region FDb may be located on the front surface FS of the substrate 100. The second floating diffusion region FDb may be spaced apart from the back surface BS of the substrate 100. The second floating diffusion region FDb may be a region formed by injecting the impurities of the first conductivity type into the semiconductor substrate. The second floating diffusion region FDb may be in contact with the wiring structure 250. The second floating diffusion region FDb may be disposed inside the second well region PWb.

The second well region PWb may be located on the front surface FS of the substrate 100. The second well region PWb may be spaced apart from the back surface BS of the substrate 100. The second well region PWb may be a region formed by injecting the impurities of the second conductivity type into the semiconductor substrate. The second well region PWb may surround the second medium node MDb and the second floating diffusion region FDb. For example, the second well region PWb may be in contact with side surfaces and a lower surface of each of the second medium node MDb and the second floating diffusion region FDb.

As a PN junction is formed between the second medium node MDb and the second floating diffusion region FDb, a capacitance may be formed in the second floating diffusion region FDb. A circuit model obtained by modeling the capacitance formed by the PN junction in a circuit diagram may correspond to the second parasitic capacitor PCb of FIG. 2.

The first separation structure STI may be located between the first and second control nodes 312a and 312b, the first and second detection nodes 314a and 314b, the first well region PWa, and the second well region PWb to electrically separate the components from each other. The first separation structure STI may have a shape in which an insulating material is buried in a trench formed by etching a portion of the front surface FS of the substrate 100. A depth of the first separation structure STI, which extends from the front surface FS to the inside of the semiconductor substrate, may be smaller than a depth of each of the first and second well regions PWa and PWb, the first and second control nodes 312a and 312b, and the first and second detection nodes 314a and 314b.

The photoelectric conversion region 330 may react to the incident light incident from the back surface BS of the substrate 100 to generate photocharges. A transfer direction of the photocharges in the photoelectric conversion region 330 may be determined depending on the control signals Va and Vb respectively applied to the first and second control nodes 312a and 312b. The photoelectric conversion region 330 may also be a region including given impurities in the semiconductor substrate.

The wiring region 210 may include a first transfer gate TXGa, a second transfer gate TXGb, the capacitor CAP, the wiring structures 250, and an interlayer insulating layer 270.

The first transfer gate TXGa may be disposed on the front surface FS of the substrate 100. The first transfer gate TXGa may partially overlap the first floating diffusion region FDa. The first transfer gate TXGa may partially overlap the first medium node MDa. The first transfer gate TXGa may be in contact with the wiring structure 250.

The second transfer gate TXGb may be disposed on the front surface FS of the substrate 100. The second transfer gate TXGb may partially overlap the second floating diffusion region FDb. The second transfer gate TXGb may partially overlap the second medium node MDb. The second transfer gate TXGb may be in contact with the wiring structure 250.

The capacitor CAP may be spaced apart from the front surface FS of the substrate 100. For example, the capacitor CAP may be disposed to be spaced apart from the front surface FS in a vertical direction. The capacitor CAP may be connected to the second floating diffusion region FDb through the wiring structure 250. The capacitor CAP may overlap the first tap region 310a. For example, the capacitor CAP may overlap the first tap region 310a when viewed in the vertical direction. The capacitor CAP may overlap the second tap region 310b. For example, the capacitor CAP may overlap the second tap region 310b when viewed in the vertical direction.

The capacitor CAP may serve to provide an additional capacitance to the second floating diffusion region FDb. As the cross-sectional area of the capacitor CAP increases, the capacitance of the capacitor CAP may increase. When the capacitor CAP overlaps the second tap region 310b and also overlaps the first tap region 310a, the cross-sectional area of the capacitor CAP may increase. As a result, the capacitance of the capacitor CAP may further increase.

As the capacitance of the capacitor CAP increases, as described with reference to FIG. 2, the second floating diffusion region FDb to which the capacitor CAP is connected may have a larger capacitance compared to the first floating diffusion region FDa not connected to the capacitor CAP; in this case, the second floating diffusion region FDb may accumulate more photocharges and may achieve the high dynamic range (HDR).

The capacitor CAP may be implemented as at least one of a metal-insulator-metal (MIM) capacitor, a metal-insulator-polysilicon (MIP) capacitor, a metal-oxide-semiconductor (MOS) capacitor, or a junction capacitor. An embodiment in which the capacitor CAP is the MIM capacitor will be described as an example.

The capacitor CAP may include a first metal layer C10, a dielectric layer C20, and a second metal layer C30. The first metal layer C10 may be an electrode layer corresponding to one electrode of the capacitor CAP. The second metal layer C30 may be an electrode layer corresponding to an opposite electrode of the capacitor CAP. The dielectric layer C20 may be disposed between the first metal layer C10 and the second metal layer C30.

Each of the first and second metal layers C10 and C30 may include a material having a conductive property. For example, each of the first and second metal layers C10 and C30 may include aluminum (Al), gold (Au), copper (Cu), tungsten (W), platinum (Pt), iridium (Ir), titanium (Ti), or an alloy using at least one thereof.

The dielectric layer C20 may include a material having an insulating property. For example, the dielectric layer C20 may include at least one of silicon oxide (SiO₂), silicon nitride (Si₃N₄), High-K dielectric, or metal oxide (e.g., aluminum oxide (Al₂O₃)). For example, the High-K dielectric may include TiO₂, BaSrTiO₃, SrTiO₃, ZrO₂, or HfO₂.

The wiring (e.g., interconnect such as metal interconnect) structures 250 may include a material whose conductivity is good. For example, each of the wiring structures 250 may include at least one of materials such as copper (Cu), aluminum (Al), tungsten (W), or polysilicon including impurities.

The wiring structure 250 in contact with the first floating diffusion region FDa may be an interconnect that connects the gate electrode of the first drive transistor DXa and the first floating diffusion region FDa. The wiring structure 250 in contact with the first transfer gate TXGa may be an interconnect for applying the transfer signal TRG to the first transfer gate TXGa. The wiring structure 250 in contact with the first medium node MDa may be an interconnect also in contact with the first detection node 314a. The wiring structure 250 in contact with the first control node 312a may be an interconnect for applying the first control signal Va to the first control node 312a.

The wiring structure 250 in contact with the second control node 312b may be an interconnect for applying the second control signal Vb to the second control node 312b. The wiring structure 250 which is in contact with the second medium node MDb may be an interconnect also in contact with the second detection node 314b. The wiring structure 250 which is in contact with the second transfer gate TXGb may be an interconnect for applying the transfer signal TRG to the second transfer gate TXGb. The wiring structure 250 which is in contact with the second floating diffusion region FDb may be an interconnect that connects the gate electrode of the second drive transistor DXb and the second floating diffusion region FDb. Also, the wiring structure 250 which is in contact with the second floating diffusion region FDb may be an interconnect for the parallel connection of the capacitor CAP and the second floating diffusion region FDb.

The interlayer insulating layer 270 may electrically separate the wiring structures 250 from each other. The interlayer insulating layer 270 may be disposed between the wiring structures 250 spaced apart from each other. The interlayer insulating layer 270 may minimize the signal interference between the wiring structures 250. The interlayer insulating layer 270 may include a material having an insulating property. For example, the interlayer insulating layer 270 may include at least one of silicon oxide (SiO₂) or silicon nitride (Si₃N₄).

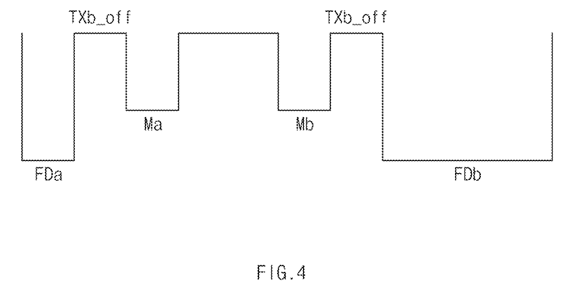

FIG. 4 is a graph illustrating an example of an electric potential distribution of the first and second floating diffusion regions FDa and FDb of the circuit diagram of FIG. 2.

Referring to FIGS. 2 and 4, when both the first tap region 310a and the second tap region 310b do not operate, all the first and second transfer transistors TXa and TXb may be in the off-state.

When the first transfer transistor TXa is in the off-state, the first transfer transistor TXa may form an electric potential barrier between the first floating diffusion region FDa and the first medium node Ma to block the charge transfer between the first floating diffusion region FDa and the first medium node Ma. The electric potential of the first floating diffusion region FDa may be lower than the electric potential of the first medium node Ma.

When the second transfer transistor TXb is in the off-state, the second transfer transistor TXb may form an electric potential barrier between the second floating diffusion region FDb and the second medium node Mb to block the charge transfer between the second floating diffusion region FDb and the second medium node Mb. The electric potential of the second floating diffusion region FDb may be lower than the electric potential of the second medium node Mb.

Because the second floating diffusion region FDb and the capacitor CAP are connected in parallel, the capacitance of the second floating diffusion region FDb may be larger than the capacitance of the first floating diffusion region FDa.

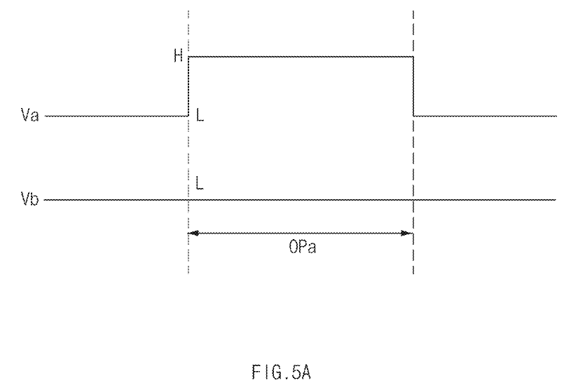

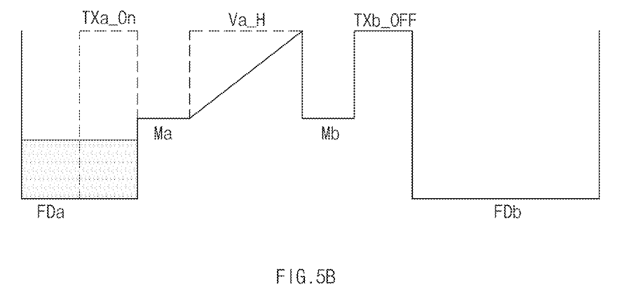

Referring to FIGS. 5A to 7B, for the purpose of describing an example operation method of the image sensing device 1 (refer to FIG. 1), three driving modes will be described as an example: a first mode in which the first tap region 310a operates in a low-illumination environment with a relatively small amount of incident light, a second mode in which the second tap region 310b operates in a high-illumination environment with a relatively large amount of incident light, and a third mode in which the first and second tap regions 310a and 310b operate in a medium-illumination environment with an amount of incident light between that of the low-illumination and high-illumination environments. The low-illumination environment may be an environment in which illuminance according to the incident light is less than a first threshold. The high-illumination environment may be an environment in which illuminance according to the incident light is greater than a second threshold that is greater than or equal to the first threshold. The medium-illumination environment may be an environment in which illuminance according to the incident light is greater than or equal to the first threshold and less than the second threshold.

FIG. 5A is a graph illustrating an example of signal levels of the first and second control signals Va and Vb when the circuit diagram of FIG. 2 operates in the first mode.

FIG. 5B is a graph illustrating an example of an electric potential distribution of the first and second floating diffusion regions FDa and FDb in an operating interval of FIG. 5A.

FIGS. 5A and 5B are diagrams for partially describing an example of an operation method of a first mode of driving the first tap region 310a in a low-illumination environment in which the amount of incident light is relatively small.

Referring to FIGS. 2, 4, 5A, and 5B, in an operating interval OPa of the first and second tap regions 310a and 310b, the first control signal Va may have a high level “H,” and the second control signal Vb may have a low level “L.” In the operating interval OPa, the first transfer transistor TXa may be in the on-state, and the second transfer transistor TXb may be in the off-state.

When the first control signal Va has the high level “H,” the first detection node 314a of the first tap region 310a may capture the photocharges generated in the photoelectric conversion region 330.

The photocharges captured at the first detection node 314a may move to the first medium node Ma and may then be transferred to the first floating diffusion region FDa through the first transfer transistor TXa of the on-state for accumulation in the first floating diffusion region FDa.

In contrast, because the second control signal Vb has the low level “L,” the second tap region 310b may not operate.

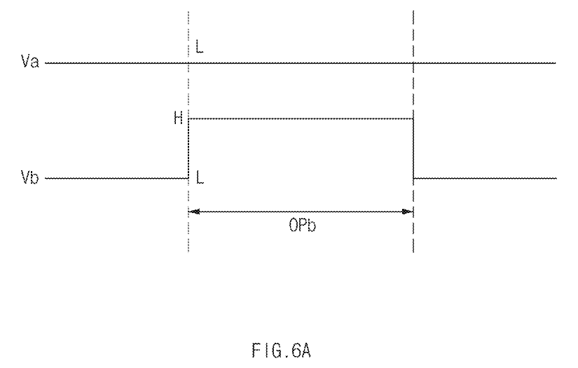

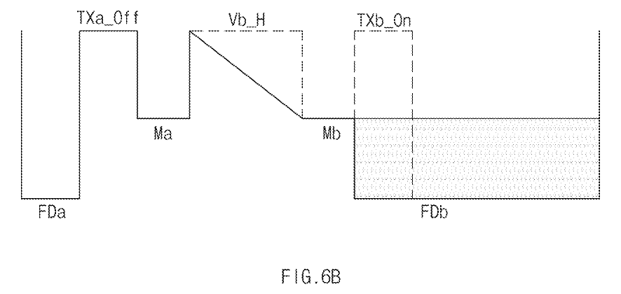

FIG. 6A is a graph illustrating an example of signal levels of the first and second control signals Va and Vb when the circuit diagram of FIG. 2 operates in the second mode.

FIG. 6B is a graph illustrating an example of an electric potential distribution of the first and second floating diffusion regions FDa and FDb in an operating interval of FIG. 6A.

FIGS. 6A and 6B are diagrams for partially describing an example of an operation method of a second mode of driving the second tap region 310b in a high-illumination environment in which the amount of incident light is relatively great.

Referring to FIGS. 2, 4, 6A, and 6B, in an operating interval OPb of the first and second tap regions 310a and 310b, the first control signal Va may have the low level “L,” and the second control signal Vb may have the high level “H.” In the operating interval OPb, the first transfer transistor TXa may be in the off-state, and the second transfer transistor TXb may be in the on-state.

Because the first control signal Va has the low level “L,” the first tap region 310a may not operate.

When the second control signal Vb has the high level “H,” the second detection node 314b of the second tap region 310b may capture the photocharges generated in the photoelectric conversion region 330.

The photocharges captured at the second detection node 314b may move to the second medium node Mb and may then be transferred to the second floating diffusion region FDb through the second transfer transistor TXb of the on-state for accumulation in the second floating diffusion region FDb.

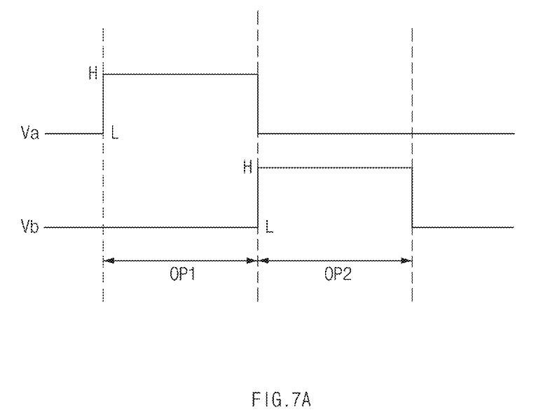

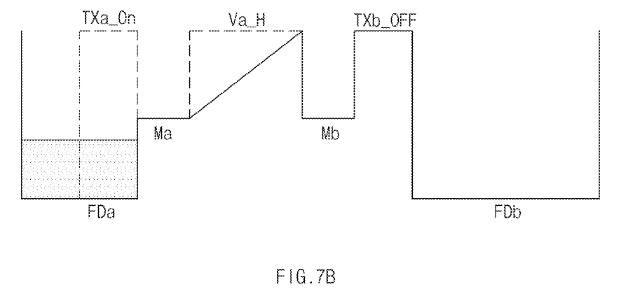

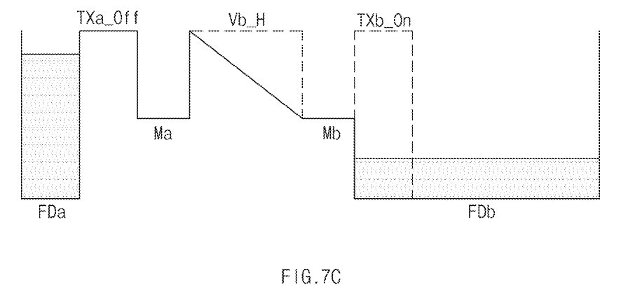

FIG. 7A is a graph illustrating an example of signal levels of the first and second control signals Va and Vb when the circuit diagram of FIG. 2 operates in the third mode.

FIG. 7B is a graph illustrating an example of an electric potential distribution of the first and second floating diffusion regions FDa and FDb in a first operating interval of FIG. 7A.

FIG. 7C is a graph illustrating an example of an electric potential distribution of the first and second floating diffusion regions FDa and FDb in a second operating interval of FIG. 7A.

FIGS. 7A to 7C are diagrams for partially describing an operation method of a third mode of driving the first tap region 310a and the second tap region 310b in the medium-illumination environment in which the amount of incident light is between the amount of incident light in the low-illumination environment and the amount of incident light in the high-illumination environment.

Referring to FIGS. 2, 4, 7A, 7B, and 7C,, a first operating interval OP1 may be an interval in which the first tap region 310a operates. A second operating interval OP2 may be an interval in which the second tap region 310b operates. According to an embodiment of the disclosed technology, the first operating interval OP1 and the second operating interval OP2 may be alternately repeated.

In the first operating interval OP1, the first control signal Va may have the high level “H,” and the second control signal Vb may have the low level “L.” In the first operating interval OP1, the first transfer transistor TXa may be in the on-state, and the second transfer transistor TXb may be in the off-state.

When the first control signal Va has the high level “H,” the first detection node 314a of the first tap region 310a may capture the photocharges generated in the photoelectric conversion region 330. The photocharges captured at the first detection node 314a may move to the first medium node Ma and may then move to the first floating diffusion region FDa through the first transfer transistor TXa of the on-state so as to be accumulated in the first floating diffusion region FDa.

Because the second control signal Vb has the low level “L,” the second tap region 310b may not operate in the first operating interval OP1.

In the second operating interval OP2, the first control signal Va may have the low level “L,” and the second control signal Vb may have the high level “H.” In the second operating interval OP2, the first transfer transistor TXa may be in the off-state, and the second transfer transistor TXb may be in the on-state.

Because the first control signal Va has the low level “L,” the first tap region 310a may not operate in the second operating interval OP2.

When the second control signal Vb has the high level “H,” the second detection node 314b of the second tap region 310b may capture the photocharges generated in the photoelectric conversion region 330. The photocharges captured at the second detection node 314b may move to the second medium node Mb and may then move to the second floating diffusion region FDb through the second transfer transistor TXb of the on-state so as to be accumulated in the second floating diffusion region FDb.

In the third mode, operations of the first and second tap regions 310a and 310b are not limited to the above embodiment. For example, in the third mode, the first and second tap regions 310a and 310b may simultaneously operate.

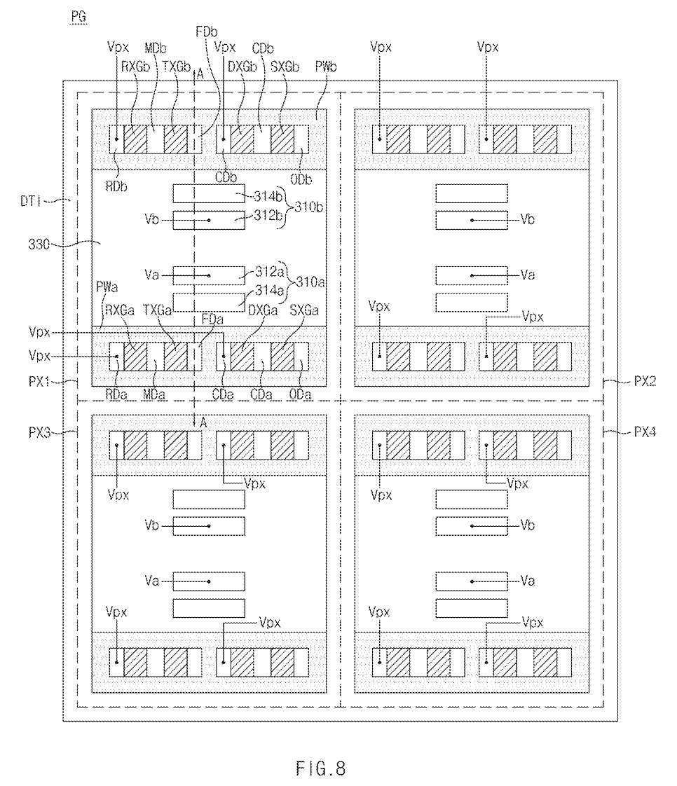

FIG. 8 is a plan view illustrating an example of a pixel group PG included in the pixel array 20 of FIG. 1.

Below, the description given with reference to FIGS. 2 and 3 will be omitted where possible.

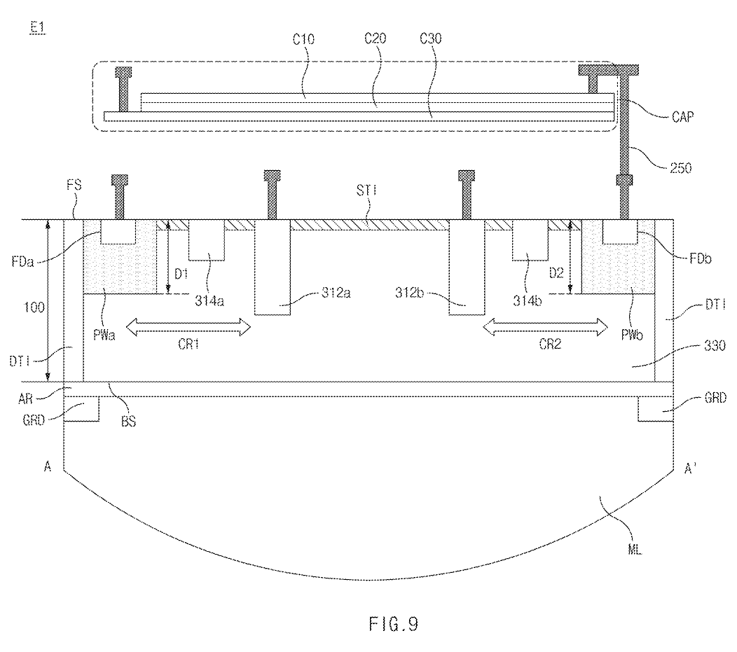

Referring to FIGS. 1, 2, 3, and 8, the pixel group PG may include first to fourth pixels PX1 to PX4. A second separation structure DTI may be disposed at the boundary between the first to fourth pixels PX1 to PX4. The second separation structure DTI may prevent or reduce the crosstalk between pixels adjacent to each other. The second separation structure DTI will be described in detail with reference to FIG. 9.

Each of the first to fourth pixels PX1 to PX4 may include substantially the same components. As an example, each of the first to fourth pixels PX1 to PX4 may include the first tap region 310a, the second tap region 310b, the photoelectric conversion region 330, the first well region PWa, the first transfer gate TXGa, a first reset gate RXGa, a first drive gate DXGa, a first select gate SXGa, the first medium node MDa, a first reset node RDa, a first connection node CDa, a first output node ODa, the first floating diffusion region FDa, the second well region PWb, the second transfer gate TXGb, a second reset gate RXGb, a second drive gate DXGb, a second select gate SXGb, the second medium node MDb, a second reset node RDb, a second connection node CDb, a second output node ODb, and the second floating diffusion region FDb.

Below, the first pixel PX1 among the first to fourth pixels PX1 to PX4 will be described as an example.

The first tap region 310a may include the first detection node 314a and the first control node 312a. The second tap region 310b may include the second detection node 314b and the second control node 312b. The first tap region 310a may be spaced apart from the second tap region 310b in one direction (hereinafter referred to as a “first direction”).

The first detection node 314a and the first control node 312a may be adjacent to each other. As an example, the first detection node 314a may be disposed to be spaced apart from the first control node 312a in the first direction. An embodiment in which the first detection node 314a and the first control node 312a are spaced apart from each other and are disposed in parallel is illustrated in FIG. 8; however, in another embodiment, the first detection node 314a may be disposed in the shape of surrounding the first control node 312a. The photoelectric conversion region 330 may be disposed between the first detection node 314a and the first control node 312a.

The second detection node 314b and the second control node 312b may be adjacent to each other. As an example, the second detection node 314b may be disposed to be spaced apart from the second control node 312b in a direction (hereinafter referred to as a “second direction”) facing away from the first direction. An embodiment in which the second detection node 314b and the second control node 312b are spaced apart from each other and are disposed in parallel is illustrated in FIG. 8; however, in another embodiment, the second detection node 314b may be disposed in the shape of surrounding the second control node 312b. The photoelectric conversion region 330 may be disposed between the second detection node 314b and the second control node 312b.

The first control node 312a may be a region to which the first control signal Va is applied. The second control node 312b may be a region to which the second control signal Vb is applied.

The photoelectric conversion region 330 may surround the first detection node 314a, the first control node 312a, the second detection node 314b, and the second control node 312b.

The first transfer gate TXGa may be the gate electrode of the first transfer transistor TXa. The first transfer gate TXGa may be a gate electrode to which the transfer signal TRG is applied. The first transfer gate TXGa may overlap the first well region PWa.

The first reset gate RXGa may be the gate electrode of the first reset transistor RXa. The first reset gate RXGa may be a gate electrode to which the reset signal RST is applied. The first reset gate RXGa may overlap the first well region PWa.

The first drive gate DXGa may be the gate electrode of the first drive transistor DXa. The first drive gate DXGa may be connected to the first floating diffusion region FDa by the wiring structure 250. The first drive gate DXGa may overlap the first well region PWa.

The first select gate SXGa may be the gate electrode of the first select transistor SXa. The first select gate SXGa may be a gate electrode to which the selection signal SEL is applied. The first select gate SXGa may overlap the first well region PWa.

The first reset node RDa may be a region including the impurities of the first conductivity type. The first reset node RDa may be disposed on one side of the first reset gate RXGa. The first reset node RDa may be disposed in the first well region PWa. The first reset node RDa may be a region to which the pixel voltage Vpx is applied through the given wiring structure 250.

The first medium node MDa may be a region including the impurities of the first conductivity type. The first medium node MDa may be disposed on an opposite side of the first reset gate RXGa. The first medium node MDa may be disposed on one side of the first transfer gate TXGa. The first medium node MDa may be disposed in the first well region PWa. The first medium node MDa may be connected to the first detection node 314a by the given wiring structure 250.

The first floating diffusion region FDa may be a region including the impurities of the first conductivity type. The first floating diffusion region FDa may be disposed on an opposite side of the first transfer gate TXGa. The first floating diffusion region FDa may be disposed in the first well region PWa. The first floating diffusion region FDa may be connected to the first drive gate DXGa by the given wiring structure 250.

The first connection node CDa may be a region including the impurities of the first conductivity type. The first connection node CDa may be disposed on one side of the first drive gate DXGa. The first connection node CDa may also be disposed on an opposite side of the first drive gate DXGa. The first connection node CDa may be disposed in the first well region PWa. The first connection node CDa disposed on one side of the first drive gate DXGa may be a region to which the pixel voltage Vpx is applied through the given wiring structure 250. The first connection node CDa disposed on an opposite side of the first drive gate DXGa may be located on one side of the first select gate SXGa.

The first output node ODa may be a region including the impurities of the first conductivity type. The first output node ODa may be disposed on an opposite side of the first select gate SXGa. The first output node ODa may be disposed in the first well region PWa. The first output node ODa may be a region which is connected to the readout circuit 13 through the given wiring structure 250.

The first well region PWa may be a region including the impurities of the second conductivity type. The first well region PWa may be located at a position biased to one side of the center of the first pixel PX1. The first well region PWa may be in contact with the side surfaces of each of the plurality of doping regions RDa, MDa, FDa, CDa, and ODa. The first well region PWa may be disposed to be spaced apart from the first tap region 310a in the first direction.

The second transfer gate TXGb may be the gate electrode of the second transfer transistor TXb. The second transfer gate TXGb may be a gate electrode to which the transfer signal TRG is applied. The second transfer gate TXGb may overlap the second well region PWb.

The second reset gate RXGb may be the gate electrode of the second reset transistor RXb. The second reset gate RXGb may be a gate electrode to which the reset signal RST is applied. The second reset gate RXGb may overlap the second well region PWb.

The second drive gate DXGb may be the gate electrode of the second drive transistor DXb. The second drive gate DXGb may be connected to the second floating diffusion region FDb by the wiring structure 250. The second drive gate DXGb may overlap the second well region PWb.

The second select gate SXGb may be the gate electrode of the second select transistor SXb. The second select gate SXGb may be a gate electrode to which the selection signal SEL is applied. The second select gate SXGb may overlap the second well region PWb.

The second reset node RDb may be a region including the impurities of the first conductivity type. The second reset node RDb may be disposed on one side of the second reset gate RXGb. The second reset node RDb may be disposed in the second well region PWb. The second reset node RDb may be a region to which the pixel voltage Vpx is applied through the given wiring structure 250.

The second medium node MDb may be a region including the impurities of the first conductivity type. The second medium node MDb may be disposed on opposite side of the second reset gate RXGb. The second medium node MDb may be disposed on one side of the second transfer gate TXGb. The second medium node MDb may be disposed in the second well region PWb. The second medium node MDb may be connected to the second detection node 314b by the given wiring structure 250.

The second floating diffusion region FDb may be a region including the impurities of the first conductivity type. The second floating diffusion region FDb may be disposed on an opposite side of the second transfer gate TXGb. The second floating diffusion region FDb may be disposed in the second well region PWb. The second floating diffusion region FDb may be connected to the second drive gate DXGb by the given wiring structure 250.

The second connection node CDb may be a region including the impurities of the first conductivity type. The second connection node CDb may be disposed on one side of the second drive gate DXGb. The second connection node CDb may also be disposed on an opposite side of the second drive gate DXGb. The second connection node CDb may be disposed in the second well region PWb. The second connection node CDb disposed on one side of the second drive gate DXGb may be a region to which the pixel voltage Vpx is applied through the given wiring structure 250. The second connection node CDb disposed on an opposite side of the second drive gate DXGb may be located on one side of the second select gate SXGb.

The second output node ODb may be a region including the impurities of the first conductivity type. The second output node ODb may be disposed on an opposite side of the second select gate SXGb. The second output node ODb may be disposed in the second well region PWb. The second output node ODb may be a region which is connected to the readout circuit 13 through the given wiring structure 250.

The second well region PWb may be a region including the impurities of the second conductivity type. The second well region PWb may be located at a position biased to an opposite side of the center of the first pixel PX1. The second well region PWb may be in contact with the side surfaces of each of the plurality of doping regions RDb, MDb, FDb, CDb, and ODb. The second well region PWb may be disposed to be spaced apart from the second tap region 310b in the second direction.

Below, in association with the cross section taken along line A-A’ of FIG. 8, the description given with reference to FIG. 3 will be omitted where possible.

FIG. 9 is a cross-sectional view illustrating a first example configuration of the cross section taken along line A-A’ of FIG. 8.

Referring to FIGS. 1, 2, 3, 8, and 9, a first cross section E1 which is the cross section of the first example configuration taken along line A-A’ of FIG. 8 may include the substrate 100, the wiring structure 250, the capacitor CAP, an anti-reflection layer AR, a grid structure GRD, and a microlens ML.

The substrate 100 may include the back surface BS onto which the incident light is incident, and the front surface FS facing away from the back surface BS. The substrate 100 may include the first detection node 314a, the first control node 312a, the first well region PWa, the first floating diffusion region FDa, the second detection node 314b, the second control node 312b, the second well region PWb, the second floating diffusion region FDb, the photoelectric conversion region 330, the first separation structure STI, and the second separation structure DTI.

Each of the first detection node 314a, the first control node 312a, the first well region PWa, the second detection node 314b, the second control node 312b, and the second well region PWb may extend from the front surface FS to the inside of the substrate 100 as much as a given depth.

In embodiments of the disclosed technology, the depth of the first control node 312a may be larger than or equal to the depth of the second control node 312b. The depth of the second control node 312b may be larger than or equal to the depth of the second well region PWb.

When the depth of the first control node 312a is larger than or equal to the depth of the second control node 312b, the magnitude of a first current CR1 flowing between the first control node 312a and the first well region PWa may be greater than or equal to the magnitude of a second current CR2 flowing between the second control node 312b and the second well region PWb. When the first current CR1 is greater than or equal to the second current CR2, a speed at which photocharges are collected at the first detection node 314a may be faster than a speed at which photocharges are collected at the second detection node 314b.

According to the first example configuration, the first detection node 314a and the second detection node 314b may have the same depth, but a difference may be present between the depths of the first detection node 314a and the second detection node 314b due to process limitations or variables. The first control node 312a and the second control node 312b may have the same depth, but there may be a difference between the depths of the first control node 312a and the second control node 312b due to process limitations or variables. The depth of the first control node 312a may be deeper than the depth of the first detection node 314a. The depth of the second control node 312b may be deeper than the depth of the second detection node 314b.

The first well region PWa may be formed inside the substrate 100 as much as a first depth D1 from the front surface FS. The second well region PWb may be formed inside the substrate 100 as much as a second depth D2 from the front surface FS. The first depth D1 may be identical to the second depth D2, but there may be a difference between the first depth D1 and the second depth D2 due to process limitations or variables.

Because the depth of the first well region PWa is identical to the depth of the second well region PWb, the first current CR1 and the second current CR2 may have substantially the same magnitude in the photoelectric conversion region 330. Accordingly, the speed at which photocharges are captured at the first detection node 314a may be similar to the speed at which photocharges are captured at the second detection node 314b.

To electrically separate the first well region PWa, the first detection node 314a, the first control node 312a, the second well region PWb, the second detection node 314b, and the second control node 312b from one another, the first separation structure STI may be disposed therebetween. In another embodiment, the first well region PWa, the first detection node 314a, the first control node 312a, the second well region PWb, the second detection node 314b, and the second control node 312b may be formed without the first separation structure STI.

The second separation structure DTI may be disposed at opposite boundaries of a pixel. In structure, the second separation structure DTI may extend from the front surface FS to the inside of the substrate 100. For example, the second separation structure DTI may be extended from the front surface FS to the back surface BS. The second separation structure DTI may include a conductive layer and an insulating layer surrounding the conductive layer. The conductive layer may include, for example, poly-silicon containing impurities. The insulating layer may include, for example, silicon oxide or zircon nitride. The second separation structure DTI may prevent the crosstalk between adjacent pixels, which is caused when a light is incident to the inside of the substrate 100 through the back surface BS.

The anti-reflection layer AR may be disposed to be in contact with the back surface BS. The anti-reflection layer AR may reduce a ratio at which the incident light incident onto the substrate 100 through the microlens ML is reflected. The anti-reflection layer AR may include, for example, silicon nitride. The anti-reflection layer AR may have a stacked structure in which a plurality of materials are stacked.

The grid structure GRD may be disposed in the vicinity of the boundary of the pixel. The grid structure GRD may prevent the crosstalk between adjacent pixels when a light passes through the microlens ML. As an example, the grid structure GRD may include a material (e.g., air) with high reflectivity. As another example, the grid structure GRD may include a material (e.g., tungsten (W)) with high absorptance.

The microlens ML may focus the light to be incident onto the pixel on the substrate 100. An incident surface through which the incident light is incident onto the microlens ML may be in the shape of a curved surface. An optical filter (not illustrated) may be further disposed between the microlens ML and the back surface BS. The optical filter may selectively transmit the light of a specific wavelength (e.g., a green wavelength, a red wavelength, or a blue wavelength).

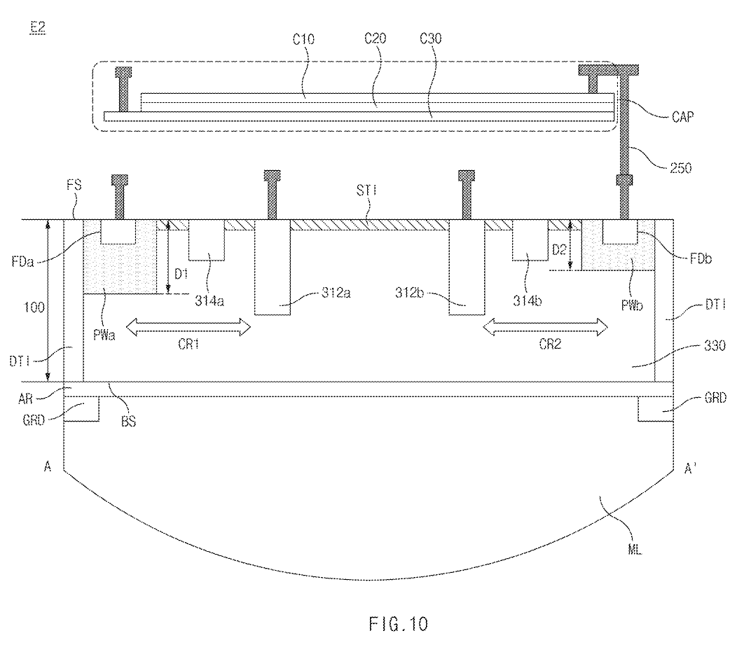

FIG. 10 is a cross-sectional view illustrating a second example configuration of the cross section taken along line A-A’ of FIG. 8.

Referring to FIGS. 1, 2, 3, 8, and 10, a second cross section E2 which is the cross section of the second example configuration taken along line A-A’ of FIG. 8 may include the substrate 100, the wiring structure 250, the capacitor CAP, the anti-reflection layer AR, the grid structure GRD, and the microlens ML.

Below, the description given with reference to FIG. 9 will be omitted where possible, and differences from FIG. 9 will be mainly described.

The first depth D1 of the first well region PWa may be larger than the second depth D2 of the second well region PWb. For example, the first depth D1 may be closer to the depth of the first control node 312a than the depth of the first detection node 314a. The second depth D2 may be closer to the depth of the second detection node 314b than the depth of the second control node 312b.

When designing the depths of the detection nodes 314a and 314b, the control nodes 312a and 312b, and the well regions PWa and PWb under the above condition, the first detection node 314a connected to the first floating diffusion region FDa having a relatively smaller capacitance may provide a faster photo charge capture speed than the second detection node 314b connected to the second floating diffusion region FDb having a relatively large capacitance through the connection with the capacitor CAP. This may enable more efficient photocharges capture in the low-illumination environment.

Assuming that the depth of the first well region PWa including the first floating diffusion region FDa and adjacent to the first control node 312a increases, when the first control signal Va of the high level is applied to the first control node 312a, the first current CR1 may be formed to be relatively larger. Assuming that the image sensing device 1 operates in the first mode in the low-illumination environment, as the first current CR1 becomes larger, the photo charge capture speed through the first detection node 314a may increase. Also, as the depth of the second well region PWb including the second floating diffusion region FDb and adjacent to the second control node 312b decreases, the second current CR2 may be formed to be relatively smaller, and the photocharges generated in the photoelectric conversion region 330 may be captured very quickly to the first detection node 314a.

Compared to the first example configuration described above and third and fourth example configurations to be described below, in the second example configuration, the amount of first current CR1 has the largest magnitude, that is, the photo charge capture speed of the first detection node 314a is the highest.

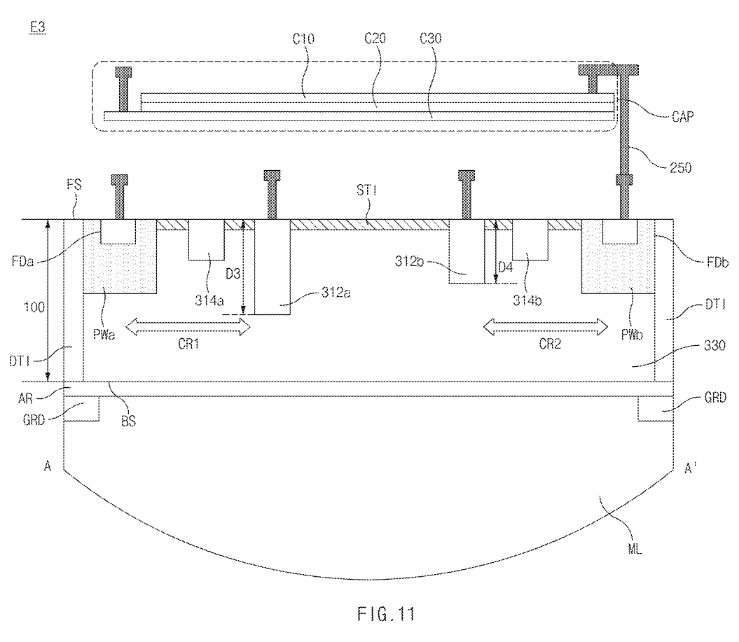

FIG. 11 is a cross-sectional view illustrating a third example configuration of the cross section taken along line A-A’ of FIG. 8.

Referring to FIGS. 1, 2, 3, 8, and 11, a third cross section E3 which is the cross section of the third example configuration taken along line A-A’ of FIG. 8 may include the substrate 100, the wiring structure 250, the capacitor CAP, the anti-reflection layer AR, the grid structure GRD, and the microlens ML.

Below, the description given with reference to FIG. 9 will be omitted where possible, and a difference with FIG. 9 will be mainly described.

A third depth D3 of the first control node 312a may be larger than a fourth depth D4 of the second control node 312b. For example, the third depth D3 may be larger than the first depth D1 of the first well region PWa and the second depth D2 of the second well region PWb. The fourth depth D4 may be smaller than the first depth D1 and the second depth D2.

In the case of forming the fourth depth D4 of the second control node 312b to be relatively shallow, when the second control signal Vb of the high level is applied to the second control node 312b, the magnitude of the second current CR2 may be relatively small. Also, the third depth D3 of the first control node 312a may be formed relatively deeply, and thus, the magnitude of the first current CR1 may be relatively greater than the magnitude of the second current CR2.

The third example configuration may enable a difference in charge collection efficiency between the first control node 312a and the second control node 312b by making the magnitudes of the first current CR1 and the second current CR2 different. Because the amount of current is reduced compared to the second example configuration, the third example configuration may be advantageous in terms of power consumption.

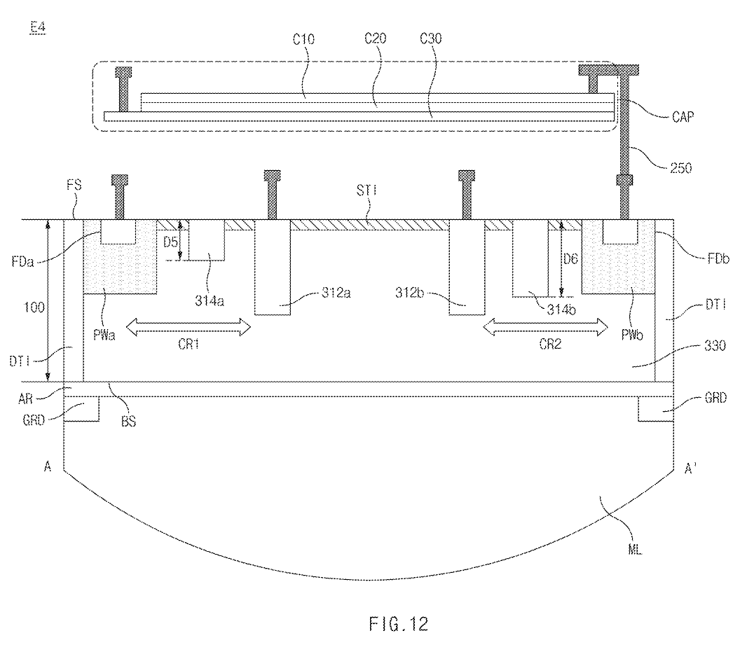

FIG. 12 is a cross-sectional view illustrating a fourth example configuration of the cross section taken along line A-A’ of FIG. 8.

Referring to FIGS. 1, 2, 3, 8, and 12, a fourth cross section E4 which is the cross section of the fourth example configuration taken along line A-A’ of FIG. 8 may include the substrate 100, the wiring structure 250, the capacitor CAP, the anti-reflection layer AR, the grid structure GRD, and the microlens ML.

Below, the description given with reference to FIG. 9 will be omitted where possible, and a difference with FIG. 9 will be mainly described.

A fifth depth D5 of the first detection node 314a may be smaller than a sixth depth D6 of the second detection node 314b. For example, the fifth depth D5 may be smaller than the first depth D1 of the first well region PWa and the second depth D2 of the second well region PWb. For example, the sixth depth D6 may be larger than the first depth D1 and the second depth D2.

When the depth of the second detection node 314b increases, the resistance between the second control node 312b to which the second control signal Vb is applied and the second floating diffusion region FDb may increase; in this case, the magnitude of the second current CR2 may decrease. Because the fifth depth D5 is smaller than the sixth depth D6, the magnitude of the first current CR1 may be relatively greater than the magnitude of the second current CR2.

Because the magnitude of the first current CR1 is small compared to the second example configuration, the fourth example configuration may be advantageous in terms of power consumption. Also, a sufficient amount of photocharges may be captured in the high-illumination environment in that the sensitivity increases due to the increase in the size of the second detection node 314b and more photocharges are accumulated in the second detection node 314b having a relatively large capacitance.

The first to fourth pixels PX1 to PX4 included in the pixel group PG of FIG. 8 may have any one cross section among the cross sections of the first to fourth example configurations, which are taken along line A-A’ of FIG. 8.

As an example, all the first to fourth pixels PX1 to PX4 may have the cross-sectional structure according to the first example configuration. As another example, some of the first to fourth pixels PX1 to PX4 may have the cross-sectional structure according to the first example configuration, and the others thereof may have the cross-sectional structure according to any one of the second to fourth example configurations.

Furthermore, according to an embodiment of the disclosed technology, because a central region of the pixel array 20 receives a relatively large amount of incident light due to the lens shading phenomenon, the central region of the pixel array 20 may include many pixels each having the cross section (e.g., the fourth example configuration) whose structure is advantageous in the high-illumination environment. Because an edge region of the pixel array 20 receives a relatively small amount of incident light due to the lens shading phenomenon, the edge region of the pixel array 20 may include relatively more pixels each having the cross section (e.g., the second example configuration) whose structure is advantageous in the low-illumination environment.

Embodiments of the disclosed technology may be designed to have an appropriate one of the cross-sectional structures of the first to fourth example configurations, considering the location of each pixel in a pixel array or a characteristic required for each pixel.

An embodiment of the disclosed technology may provide an image sensing device having a wider dynamic range by including a plurality of floating diffusion regions having different capacitances in a unit pixel.

An embodiment of the disclosed technology may provide an image sensing device with a further increased dynamic range by maximizing the capacitance difference between a plurality of floating diffusion regions included in a unit pixel, thereby maximizing the conversion gain difference.

An embodiment of the disclosed technology may provide an image sensing device designed to output an electric signal having different dynamic ranges for the same exposure time in a unit pixel.

An embodiment of the disclosed technology may provide an image sensing device designed to operate in a global shutter mode while maintaining a wide dynamic range. In some embodiments, the term “global shutter mode” refers to an operation mode in which all pixels of the pixel array start and end exposure simultaneously, thereby capturing image data corresponding to the same time interval.

As explained above, some embodiments of the discloses technology provide an image sensing device employing a two-tap pixel architecture implemented based on indirect Time-of-Flight technology, adapted for high dynamic range (HDR) imaging with global shutter operation. In some embodiments, each pixel includes a first tap region and a second tap region, each configured to capture photocharges from a photoelectric conversion region. The first and second tap regions are associated with floating diffusion (FD) regions having different capacitances, enabling different conversion gains. In some embodiments, the second FD region is coupled to an additional capacitor connected in parallel to adjust its effective capacitance, thereby increasing the saturation charge capacity for high-illuminance conditions. By sequentially or selectively operating the two tap regions, the image sensing device can capture at least two images under different conversion gain values (difference effective capacitance values) within the same exposure period. These images are then combined to produce an HDR image while preventing motion distortion through the global shutter mode operation.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a semiconductor substrate; and
a pixel array supported by the semiconductor substrate and including a plurality of pixels, each of the plurality of pixels including a photoelectric conversion region configured to generate electrical signals in response to incident light,
wherein each of the plurality of pixels further includes:
a first tap region and a second tap region disposed in the semiconductor substrate, wherein each of the first and second tap regions configured to capture photocharges generated by the photoelectric conversion region;
a first floating diffusion region disposed in the semiconductor substrate and coupled to the first tap region, the first floating diffusion region having a first capacitance and configured to accumulate the photocharges captured by the first tap region;
a second floating diffusion region disposed in the semiconductor substrate and coupled to the second tap region, the second floating diffusion region having a second capacitance and configured to accumulate the photocharges captured by the second tap region; and
a capacitor electrically connected in parallel to the second floating diffusion region and configured to modify an effective capacitance of the second floating diffusion region having the second capacitance.

2. The image sensing device of claim 1, wherein the capacitor at least partially overlaps the first tap region or the second tap region or both the first and second tap regions.

3. The image sensing device of claim 1, further comprising:
a first well region surrounding the first floating diffusion region and having a first depth from a first surface of the semiconductor substrate; and
a second well region surrounding the second floating diffusion region and having a second depth from the first surface of the semiconductor substrate.

4. The image sensing device of claim 3, wherein the first depth is larger than the second depth.

5. The image sensing device of claim 3, wherein the first tap region includes a first control node having a third depth from the first surface of the semiconductor substrate, and
wherein the second tap region includes a second control node having a fourth depth from the first surface of the semiconductor substrate.

6. The image sensing device of claim 5, wherein the third depth is larger than the fourth depth.

7. The image sensing device of claim 5, wherein the first tap region further includes a first detection node having a fifth depth from the first surface of the semiconductor substrate and configured to capture the photocharges, and
wherein the second tap region further includes a second detection node having a sixth depth from the first surface of the semiconductor substrate and configured to capture the photocharges.

8. The image sensing device of claim 7, wherein the fifth depth is smaller than the sixth depth.

9. The image sensing device of claim 7, wherein each of the first floating diffusion region, the second floating diffusion region, the first detection node, and the second detection node includes impurities of a first conductivity type, and
wherein each of the first well region, the second well region, the first control node, and the second control node include impurities of a second conductivity type.

10. The image sensing device of claim 1, wherein the first tap region operates in a first mode in which illuminance according to the incident light is less than a first threshold, and
wherein the second tap region operates in a second mode in which the illuminance according to the incident light is greater than a second threshold that is greater than or equal to the first threshold.

11. The image sensing device of claim 10, wherein an electrical signal corresponding to photocharges accumulated in the first floating diffusion region is generated in response to operation of the first tap region, and
wherein an electrical signal corresponding to photocharges accumulated in the second floating diffusion region is generated in response to operation of the second tap region.

12. The image sensing device of claim 10, wherein both the first tap region and the second tap region operate in a third mode in which the illuminance according to the incident light is between the first threshold and the second threshold.

13. The image sensing device of claim 12, wherein the first tap region and the second tap region operate alternately in the third mode.

14. The image sensing device of claim 1, wherein the pixel array operates in a global shutter mode.

15. An image sensing device comprising:
a substrate including: a photoelectric conversion region configured to generate photocharges in response to incident light; a first tap region; and a second tap region, wherein each of the first and second tap regions is configured to capture the photocharges; and
a capacitor spaced apart from a first surface of the substrate and vertically overlapping the second tap region.

16. The image sensing device of claim 15, wherein the capacitor vertically overlaps the first tap region.

17. The image sensing device of claim 15, wherein the substrate further includes:
a first floating diffusion region electrically connected to the first tap region by a first transfer transistor;
a first well region surrounding the first floating diffusion region and having a first depth from the first surface of the substrate;
a second floating diffusion region electrically connected to the second tap region by a second transfer transistor; and
a second well region surrounding the second floating diffusion region and having a second depth from the first surface of the substrate, and
wherein the capacitor and the second floating diffusion region are electrically connected in parallel.

18. The image sensing device of claim 17, wherein the first depth is larger than the second depth.

19. The image sensing device of claim 17, wherein the first tap region includes a first control node having a third depth from the first surface of the substrate, and
wherein the second tap region includes a second control node having a fourth depth from the first surface of the substrate.

20. The image sensing device of claim 19, wherein the third depth is larger than the fourth depth.

21. The image sensing device of claim 19, wherein the first tap region further includes a first detection node having a fifth depth from the first surface of the substrate, and
wherein the second tap region further includes a second detection node having a sixth depth from the first surface of the substrate.

22. The image sensing device of claim 21, wherein the fifth depth is smaller than the sixth depth.
